(19) United States
(12) Patent Application Publication
(10) Pub. No.: US 2021/0408080 A1
(43) Pub. Date: Dec. 30, 2021

(54) THIN FILM TRANSISTOR ARRAY SUBSTRATE, MANUFACTURING METHOD THEREOF, AND DISPLAY PANEL

(71) Applicant: WUHAN CHINA STAR OPTOELECTRONICS TECHNOLOGY CO., LTD., Wuhan, Hubei (CN)

(72) Inventors: Fei AI, Wuhan, Hubei (CN); Dewei SONG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 16/757,175

(22) PCT Filed: Dec. 12, 2019
(86) PCT No.: PCT/CN2019/124855

§ 371 Date: Apr. 17, 2020

(30) Foreign Application Priority Data
Nov. 26, 2019 (CN) 201911172589.2

(51) Int. Cl. H01L 27/12; G02F 1/1368; G02F 1/1343; G02F 1/136

(52) U.S. Cl. CPC H01L 27/1248; H01L 27/124; H01L 27/1259; G02F 1/136227; G02F 1/134318; G02F 1/13606; G02F 1/13439; G02F 1/13685

(57) ABSTRACT

The invention provides a thin film transistor (TFT) array substrate, a manufacturing method thereof, and a display panel. The TFT array substrate includes a substrate. A buffer layer and a TFT functional layer are sequentially disposed on the substrate. The TFT functional layer includes an active layer (Active), a gate insulating layer (GI), a gate layer (GE), an interlayer insulating layer (ILD), and a source-drain layer (SD) that are sequentially disposed on the buffer layer. An inorganic insulating layer is disposed on the source-drain layer, and a backside indium tin oxide (BITO) layer, a passivation layer (PV), and a top indium tin oxide (TITO) layer are sequentially disposed on the inorganic insulating layer. The invention provides the TFT array substrate. The TFT array substrate adopts a new functional layer structure design, which can effectively reduce production cost and cycle time of the TFT array substrate.

### CROSS REFERENCE TO RELATED APPLICATION

The present application claims priority of a Chinese patent application filed with the National Intellectual Property Administration on Nov. 26, 2019, application No. 201911172589.2, titled “Thin film transistor array substrate, manufacturing method thereof, and display panel”, which is incorporated by reference in the present application in its entirety.

### FIELD OF INVENTION

The present application relates to the technical field of display panels, and in particular, to an array substrate, a manufacturing method thereof, and a display panel.

### BACKGROUND OF INVENTION

It is well known that with continuous development of display technologies, flat-display technology has replaced cathode ray tube (CRT) display technology to become a mainstream display technology.

Flat-panel display devices such as liquid crystal display (LCD) are widely applied to a variety of consumer electronics, such as mobile phones, televisions, personal digital assistants, digital cameras, notebook computers, and desktop computers, due to their advantages including high definition, power saving, thinness, and wide application range, and have become mainstream of display devices.

In particular, low temperature poly-silicon (LTPS) display technology, because of its relatively high carrier mobility, enables transistors to obtain a higher current on/off ratio. Under a condition of meeting a required charging current, each pixel transistor can be made smaller, light transmission area of each pixel can be increased, an aperture ratio of panel can be increased, light spots of the panel can be solved, resolution can be enhanced, and power consumption can be reduced, thereby achieving a better visual experience.

However, since liquid crystal displays are passive display devices relying on an electric field to adjust orientations of liquid crystal molecules to realize light flux modulation, a refined active driving array is required to match a deflection of the liquid crystals in each pixel area.

In view of LTPS active array continuously developing in a direction of reduced sizes, subsequent advancements in lithography technology have led to an exponential increase in equipment costs. Therefore, it is necessary to develop a new type of thin-film transistor (TFT) array substrate to overcome defects in the prior art.

### Technical Problem

One aspect of the present invention is to provide a thin-film transistor (TFT) array substrate which adopts a new functional layer structure design, which can effectively reduce production cost and production cycle time of the TFT array substrate.

### SUMMARY OF INVENTION

The technical solution adopted by the present invention is as follows:

A thin film transistor (TFT) array substrate, including a substrate. The substrate sequentially provided with a buffer layer and a TFT functional layer thereon. Wherein the TFT functional layer includes an active layer (Active), a gate insulating layer (GI), a gate layer (GE), an interlayer insulating layer (ILD), and a source-drain layer (SD) sequentially disposed on the buffer layer. Wherein the source-drain layer is provided with an inorganic insulating layer (IL) thereon, the inorganic IL layer is sequentially provided with a back side indium tin oxides (BITO) layer, a passivation layer (PV), and a top-indium tin oxides (TITO) layer thereon.

Further, in a different embodiment, a first through-slot is disposed in the BITO layer positioned above the source-drain layer, and the passivation layer fills the first through-slot and contacts with a surface of the inorganic insulating layer.

Further, in a different embodiment, a width of the first through-slot is less than or equal to a width of the source-drain layer disposed underneath.

Further, in a different embodiment, the material of the inorganic insulating layer includes SiN and/or SiO, which can be determined as needed and is not limited.

Further, in a different embodiment, the array substrate is a low-temperature poly-silicon (LPTS) type array substrate.

Further, in a different embodiment, a light-shielding layer is disposed in the buffer layer.

Further, in a different embodiment, a material used for the active layer is a low-temperature polysilicon (Poly-Si) material.

Further, another aspect of the present invention is to provide a method of manufacturing the array substrate according to the present invention, including following steps: step S1: forming a light-shielding layer on a substrate; step S2: forming a buffer layer and an active layer on the substrate; step S3: forming a gate insulating layer and a gate layer on the buffer layer; step S4: forming an interlayer insulating layer on the gate insulating layer; step S5: forming a source-drain layer on the interlayer insulating layer; step S6: forming an inorganic insulating layer on the interlayer insulating layer, and forming a BITO layer on the inorganic insulating layer; step S7: forming a passivation layer on the inorganic insulating layer; and step S8: forming a TITO layer on the passivation layer.

Further, in a different embodiment, in the step S6, after forming the BITO layer, further performing a slotting process on the BITO layer positioned above the source-drain layer to form a first through-slot; and in the step S7, the passivation layer fills the first through-slot and contacts with a surface of the inorganic insulating layer.

Further, another aspect of the present invention is to provide a display panel including the array substrate of the present invention.

Further, in a different embodiment, the display panel is a liquid crystal display (LCD) panel.

Further, in a different embodiment, the source-drain (SD) layer in the array substrate is configured to data traces in the display panel, and the BITO layer provided thereon is configured to common (Com) electrodes. The BITO layer adopts a method of providing a first through-slot, which can effectively reduce the couple capacitance between the BITO layer and the source-drain layer correspondingly provided below, thereby, the optical problems such as crosstalk and abnormal reloading display that may occur on the display panel can be avoided, which further optimizing product design and improving the optical performances of the display panel.

Further, in a different embodiment, the first through-slot provided in the BITO layer above the source-drain layer is positioned between two adjacent gate traces (Gate) disposed in the display panel.

Compared with the prior art, the beneficial effects of the present invention are: The invention relates to a TFT array substrate, which adopts a new functional layer structure design. The structure for separating the source-drain layer and the BITO layer is not a planarization layer (PLN) commonly used in the industry, but a structure using an inorganic insulating layer, which reduces a mask process for the planarization layer in the overall manufacturing process. Therefore, the manufacturing process is relatively simplified and the production cost and the cycle time of the TFT array substrate of the present invention are reduced.

Further, in the TFT array substrate according to the present invention, the corresponding BITO layer positioned above the source-drain (SD) layer adopts a new structure design. That is, by the structural design of the internal slotting of the BITO layer, the couple capacitance value between the source-drain layers serving as data traces and the BITO layer serving as Com electrodes can be effectively reduced. Therefore, optical problems such as crosstalk and abnormal overloaded display that may occur in the display panel are avoided, thereby optimizing the product design and improving the optical performances of the display panel.

### Beneficial Effect

The beneficial effects of the application are: Performing inverse quantization on the image compression data based on inverse quantization factor of an integer to obtain inverse quantized data, and further performing DCT inverse transformation on the inverse quantized data based on a shift operation and an addition operation to obtain image data. This enables an image decompression process free of floating-point operations and multiplication operations, which effectively improves the efficiency of decompression and ensures real-time processing of decompression.

### DESCRIPTION OF DRAWINGS

The specific implementation of the present application will be described in detail below with reference to the accompanying drawings to make the technical solution and other beneficial effects of the present application clear.

FIG. 1 is a schematic structural diagram of a conventional TFT array substrate.

FIG. 2 is a schematic diagram showing a TFT array substrate after step Si is completed in a manufacturing process of the present invention.

FIG. 3 is a schematic diagram showing a TFT array substrate after step S2 is completed in the manufacturing process of the present invention.

FIG. 4 is a schematic diagram showing a TFT array substrate after step S3 is completed in the manufacturing process of the present invention.

FIG. 5 is a schematic diagram showing a TFT array substrate after step S4 is completed in the manufacturing process of the present invention.

FIG. 6 is a schematic diagram showing a TFT array substrate after step SS is completed in the manufacturing process of the present invention.

FIG. 7 is a schematic diagram showing a TFT array substrate after step S6 is completed in the manufacturing process of the present invention.

FIG. 8 is a schematic diagram showing a TFT array substrate after step S7 is completed in the manufacturing process of the present invention.

FIG. 9 is a schematic diagram showing a TFT array substrate after step S8 is completed in the manufacturing process of the present invention.

FIG. 10 is a schematic plan perspective view of a partial structure of a display panel according to the present invention.

### DETAILED DESCRIPTION OF PREFERRED EMBODIMENTS

The specific structural and functional details disclosed herein are merely representative and are for the purpose of describing exemplary embodiments of the present application. However, the present application may be embodied in many alternate forms and should not be construed as being limited to only the embodiments set forth herein.

In the description of the present application, it should be understood that the orientational or positional relationship indicated by the terms “center”, “transverse”, “upper”, “lower”, “left”, “right”, “vertical”, “horizontal”, “top”, “bottom”, “inside”, “outside”, and the like are based on the orientation or position relationship shown in the drawings. It is only for the convenience of describing the present application and simplifying the description and does not indicate or imply that the device or element referred to must have a specific orientation, be constructed and operate in a specific orientation, and therefore cannot be understood as a limitation on the present application. In addition, the terms “first” and “second” are used for descriptive purposes only and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless it is specifically defined otherwise. Moreover, the term “including” and any synonyms thereof are intended to cover a non-exclusive inclusion.

In the description of the present application, it should be noted that, unless otherwise specified and limited, the terms “installation”, “interconnection”, and “connection” should be understood in a broad sense, for example, it can be support connection, detachable connection, or integral connection; it can be mechanical connection or electrical connection; it can be directly connected or connected through an intermediate medium or it can be internal connection of two elements. For those of ordinary skill in the art, the specific meanings of the above terms in the present application can be understood in specific situations.

The terminology used herein is for the purpose of describing particular embodiments only and is not intended to limit the exemplary embodiments. Unless the context clearly indicates otherwise, the singular forms “a” and “an” as used herein are intended to include the plural. It should also be understood that the terms “including” and/or “comprising” as used herein specify the presence of stated features, integers, steps, operations, units and/or components without excluding the presence or addition of one or more other features, integers, steps, operations, units, components, and/or combinations thereof.

An embodiment of the present invention provides a method of manufacturing a thin film transistor (TFT) array substrate according to the present invention, which includes following steps.

Step S1: Depositing a light shielding (LS) layer 101 on a provided substrate 100 (glass), and then performing etching to form a pattern of the light-shielding layer 101. The completed structural diagram is shown in FIG. 2.

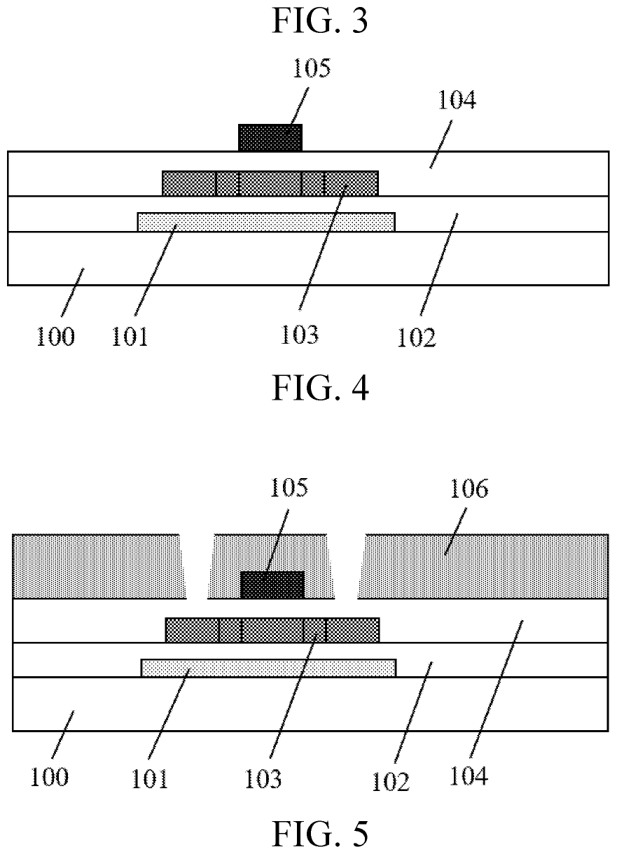

Step S2: After a buffer (BL) layer 102 is deposited on the substrate 100, an active layer 103 is deposited, a material adopted thereof is a-Si, and laser annealing is performed. Then, after photolithography (PHO)/dry etching (Dry)/stripping (STR) processes, a poly-Si pattern of the active layer 103 is formed. The completed structural diagram is shown in FIG. 3.

Step S3: A gate insulating layer (GI) 104 and a gate layer (GE) 105 disposed thereon are deposited on the buffer layer 102, and the gate layer 105 is patterned by a re-etching process technology commonly used in the industry. A heavily doped source-drain and a lightly doped drain (LDD) of the active layer 103 are formed. The completed structural diagram is shown in FIG. 4.

Step S4: An interlayer dielectric layer (ILD) 106 is deposited on the gate insulating layer, and it is patterned by PHO/Dry/STR processes commonly used in the industry to form a via pattern. The completed structural diagram is shown in FIG. 5.

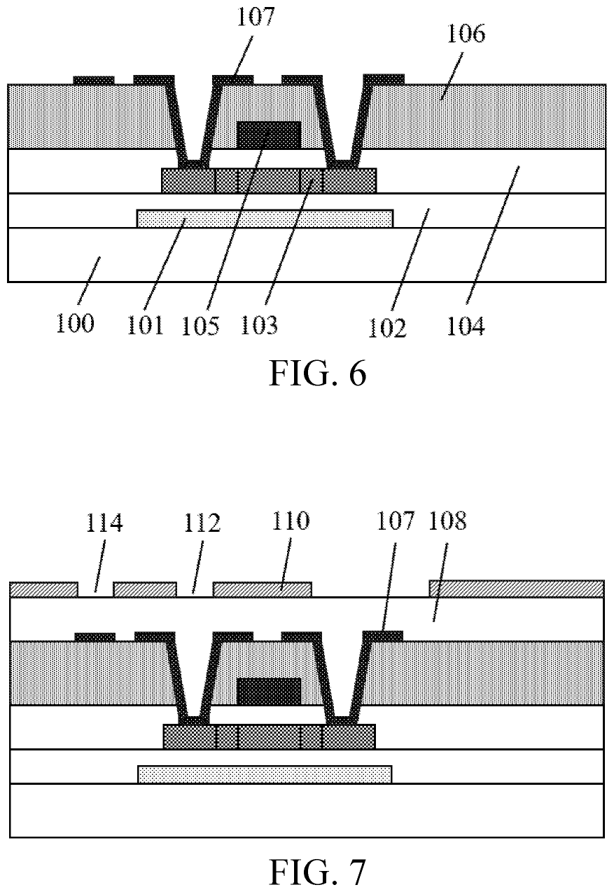

Step S5: A source-drain (SD) layer 107 is deposited on the interlayer dielectric layer, and a pattern of SD via is formed on the source-drain by PHO/Dry/STR processes commonly used in the industry. The completed structural diagram is shown in FIG. 6.

Step S6: An inorganic insulating (IL) layer 108 is deposited on the interlayer insulating layer 106 and then an indium tin oxide (ITO) material is deposited thereon. After the ITO material layer is patterned by the conventional PHO/Dry/STR processes, it is made into a backside indium tin oxide (BITO) layer 110, that is, a usual common electrode (Com ITO) is formed with a first through-slot 112 and a second through-slot 114 on the BITO layer 110 above the source-drain layer. The completed structural diagram is shown in FIG. 7.

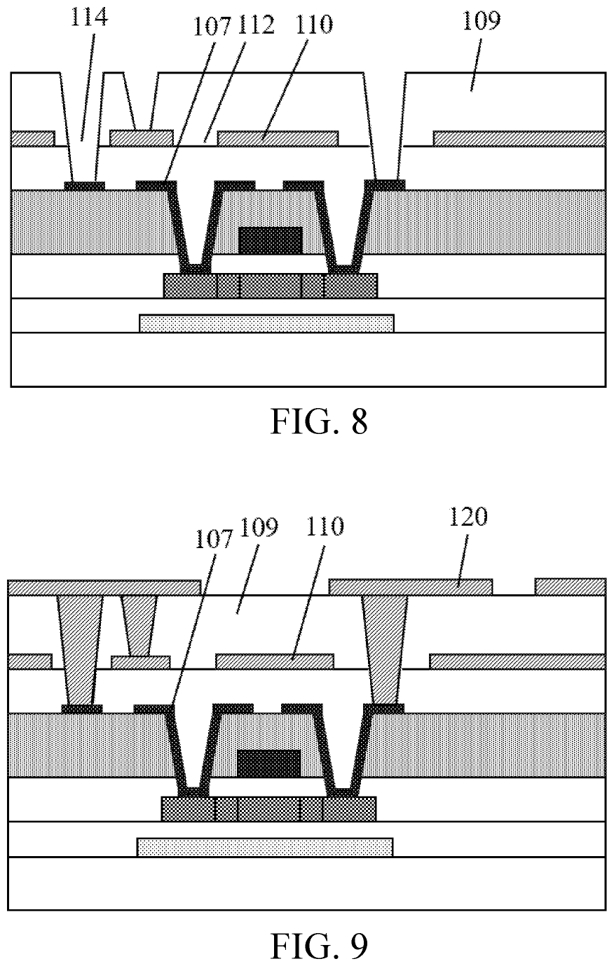

Step S7: A passivation (PV) layer 109 is deposited on the inorganic insulating layer, and then it is subjected to a patterning process by the conventional PHO/Dry/STR processes. Corresponding openings respectively reaching the source-drain layer 107 and the BITO layer 110 directly are formed, wherein one of the openings corresponding to the source-drain layer penetrates the second through-slot 114, and the first through-slot 112 is filled downward by the passivation layer 109. The completed structural diagram is shown in FIG. 8.

Step S8: The ITO material continues to be deposited on the passivation layer 109, and it is patterned by the conventional PHO/Dry/STR processes to form a TITO layer 120, which is a usual pixel electrode (pixel ITO). So far, the overall process of the TFT array substrate according to the present invention is completed. The entire structure of the TFT array substrate according to the present invention is shown in FIG. 9.

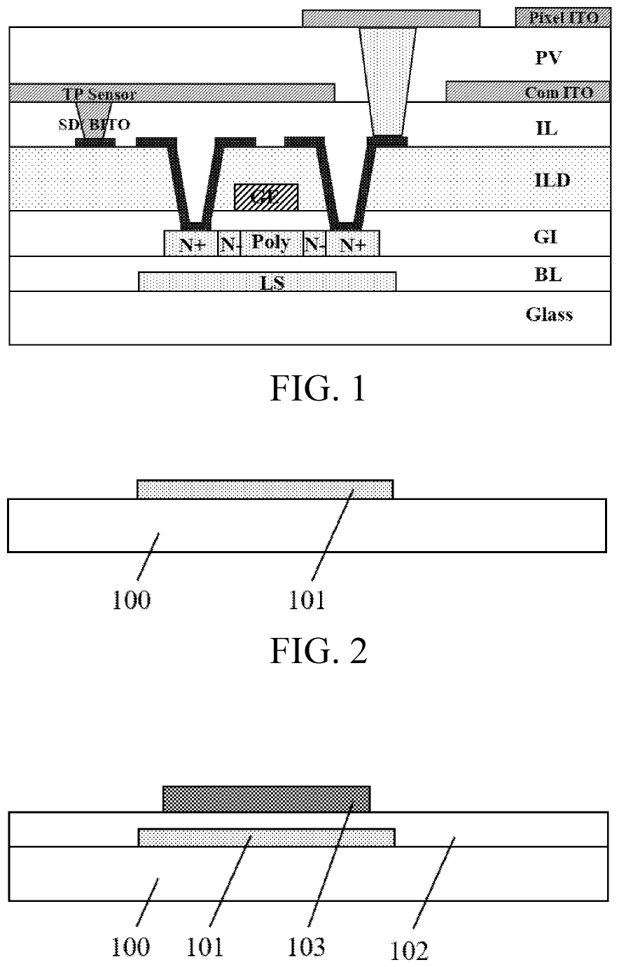

Since the TFT array substrate according to the present invention adopts an inorganic insulating layer instead of a conventional planarization layer (PLN) structural design made of organic photoresist material (please refer to the prior art structure shown in FIG. 1), therefore, compared with the conventional process of using 9 masks, the overall manufacturing process has been reduced to using 8 masks, which are used in the eight steps of the manufacturing method involved in the present invention. This way, the overall manufacturing process of the TFT array substrate according to the present invention is simplified. In addition, the production cost and cycle time of the array substrate according to the present invention are reduced.

Further, another embodiment of the present invention provides a display panel using the TFT array substrate according to the present invention.

The SD layer 107 in the array substrate is used as a data trace in the display panel, and the BITO layer 110 provided thereon is used as a Com electrode of the display panel. The first through-slot 112 is provided in the BITO layer 110, which can effectively reduce the coupling capacitance value between the BITO layer 110 and the source-drain layer 107 correspondingly provided below. Furthermore, it is possible to prevent optical problems such as crosstalk and abnormal reloading of the display panel. This way, product design is optimized and optical performance of the display panel is improved.

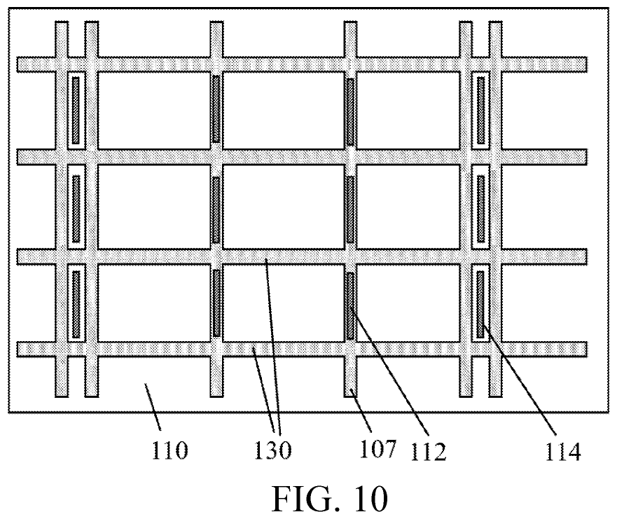

Further, the first through-slot 112 of the BITO layer 110 disposed above the source-drain layer 107 is positioned between two adjacent gate traces 130 provided in the display panel. That is, a length of the first through-slot 112 is less than a distance between the two adjacent gate traces. The specific structure is shown in FIG. 10.

As shown in FIG. 9, the BITO layer 110 is provided as a whole layer structure. In order to conveniently show a positional relationship between the BITO layer 110 and the source-drain layer 107 provided below the first through-slot 112, the corresponding source-drain layer 107 provided below are further exposed, and the first through-slot 112 is positioned between two adjacent gate traces 130 provided in the display panel, and it is perspectively illustrated. Further, the position of the second through-slot 114 is also illustrated in FIG. 9, and is positioned corresponding to the TITO layer above it to facilitate the TITO layer 120 to form a connection of the touch electrode downward.

The present application has been disclosed above with the preferred embodiments, the preferred embodiments are not intended to limit the application. Those skilled in the art can make various modifications and retouching without departing from the spirit and scope of the present application. Therefore, the protection scope of the present application is subject to the scope defined by the claims.

What is claimed is:

1. A thin film transistor (TFT) array substrate, comprising a substrate;
wherein a buffer layer and a TFT functional layer are sequentially disposed on the substrate, the TFT functional layer comprises an active layer, a gate insulating layer, a gate layer, an interlayer insulating layer, and a source-drain layer sequentially disposed on the buffer layer, an inorganic insulating layer is disposed on the source-drain layer, and a backside indium tin oxide (BITO) layer, a passivation layer, and a top indium tin oxide (TITO) layer are sequentially disposed on the inorganic insulating layer; and
wherein a first through-slot is formed in the BITO layer positioned above the source-drain layer, and the passivation layer fills the first through-slot and contacts with a surface of the inorganic insulating layer.

2. The TFT array substrate according to claim 1, wherein a width of the first through-slot is less than or equal to a width of the source-drain layer disposed underneath.

3. The TFT array substrate according to claim 1, wherein material of the inorganic insulating layer comprises SiN and/or SiO.

4. The TFT array substrate according to claim 1, wherein the passivation layer is provided with a second through-slot, the second through-slot penetrates the passivation layer and a part of the inorganic insulating layer to a surface of the source-drain layer, and the TITO layer is connected to the source-drain layer through the second through-slot.

5. The TFT array substrate according to claim 1, wherein the TFT array substrate is a low temperature poly-silicon (LPTS) type TFT array substrate.

6. A method of manufacturing the TFT array substrate of claim 1, comprising following steps:
step S1: forming a light-shielding layer on the substrate;
step S2: forming the buffer layer and the active layer on the substrate;
step S3: forming the gate insulating layer and the gate layer on the buffer layer;
step S4: forming the interlayer insulating layer on the gate insulating layer;
step S5: forming the source-drain layer on the interlayer insulating layer;
step S6: forming the inorganic insulating layer on the interlayer insulating layer, and forming the backside indium tin oxide (BITO) layer on the inorganic insulating layer;
step S7: forming the passivation layer on the inorganic insulating layer; and
step S8: forming the top indium tin oxide (TITO) layer on the passivation layer.

7. The manufacturing method according to claim 6, wherein in the step S6, after forming the BITO layer, further performing a slotting process on the BITO layer positioned above the source-drain layer to form the first through-slot; and
in the step S7, the passivation layer fills the first through-slot and contacts with the surface of the inorganic insulating layer.

8. A display panel, comprising the TFT array substrate according to claim 1.

9. The display panel according to claim 8; wherein the first through-slot is formed in the BITO layer positioned above the source-drain layer on the TFT array substrate, the passivation layer fills the first through-slot and contacts with the surface of the inorganic insulating layer, the source-drain layer in the array substrate is configured to be a data trace, and the BITO layer disposed on the source-drain layer is configured to be a common electrode.

10. The display panel according to claim 8, wherein the first through-slot is positioned between two adjacent gate traces provided in the display panel.
